(19) United States
(12) Patent Application Publication
(10) Pub. No.: US 2023/0011890 A1
(43) Pub. Date: Jan. 12, 2023

(54) ETCHING APPARATUS AND METHOD OF CONTROLLING SAME

(71) Applicant: ZEUS CO., LTD., Hwaseong-si (KR)

(72) Inventors: Seung Hoon LEE, Hwaseong-si (KR); Sung Won MO, Hwaseong-si (KR); Yang Ho LEE, Osan-si (KR); Heung Soo HAN, Osan-si (KR); Jeong Hyun BAE, Hwaseong-si (KR)

(73) Assignee: ZEUS CO., LTD., Hwaseong-si (KR)

(21) Appl. No.: 17/859,723

(22) Filed: Jul. 7, 2022

(30) Foreign Application Priority Data
Jul. 8, 2021 (KR) 10-2021-0089415

(51) Int. Cl. H01L 21/67

(52) U.S. Cl. CPC H01L 21/67075

(57) ABSTRACT

The present invention relates to an etching apparatus including an etching chamber in which a target object is etched by an etchant, an etchant supply part which collects the etchant in the etching chamber and supplies the etchant to the etching chamber using an etchant pump, a first pressure adjusting unit which injects a gas into the etchant pump to apply an operation pressure, a second pressure adjusting unit which pressurizes the etching chamber and the etchant supply part at the same predetermined pressure, a back pressure adjusting unit which adjusts a pressure of the gas discharged when the etchant pump operates, and a valve which controls an order and a direction in which the gas is injected into or discharged from the etchant pump.

### CROSS-REFERENCE TO RELATED APPLICATION

This application claims priority to and the benefit of Korean Patent Application No. 10-2021-0089415, filed on Jul. 8, 2021, the disclosure of which is incorporated herein by reference in its entirety.

### BACKGROUND

### 1. Field of the Invention

The present invention relates to an etching apparatus and a method of controlling the same, and more specifically to an etching apparatus capable of preventing damage to a bellows in an etchant pump configured to transfer an etchant from an etchant supply part to an etching chamber of the etching apparatus, and a method of controlling the same.

### 2. Discussion of Related Art

Generally, semiconductor front end processes include etching processes, and the etching processes include dry etching processes and wet etching processes.

Dry etching processes are mainly performed in a vacuum state using a fluorine-based gas and an inert gas, and since apparatuses for performing the dry etching processes are expansive, there is a limit to commercial use of the dry etching processes. Accordingly, wet etching processes using phosphoric acid are more widely used than the dry etching processes.

A wet etching process is a process of selectively etching a desired target layer from a target object (substrate or the like) through a chemical reaction and is performed using an etchant mixed and composited to have a composition ratio corresponding to required characteristics or an etch rate.

Wet etching processes have advantages of more improved process compatibility than dry etching processes, the ability to process many target objects at once, and the low prices of the apparatuses.

However, when etching is performed during a wet etching process, since an etchant is partially vaporized, a temperature of a target object may be lowered due to evaporation heat, it is difficult to control a concentration of the etchant due to evaporation of the etchant, and thus there is a disadvantage that a loss occurs. Accordingly, a method of maintaining a uniform concentration of an etchant by pressurizing an etching part (for example, including an etching chamber and an etchant supply part), that is, forming the etching part as a pressurizing system pressurized at a predetermined pressure, to prevent a vaporization phenomenon of the etchant in the etching part is required.

However, when the etching part is pressurized as described above (that is, the etching part is formed as the pressurizing system), and an etchant pump is driven in a high-temperature pressurized state, a phenomenon in which a pump bellows is deformed (for example, expanded) due to a difference between pressures and temperatures of an inside and outside of the pump and comes into contact with an inner wall (for example, an inner guide) of the pump occurs, and as friction between the pump bellows and the inner wall continues, damage to a part occurs (for example, a phenomenon in which a friction portion of the bellows is worn occurs), which reduces the lifetime, degrades performance of the pump, and may ultimately cause an incident when the bellows breaks in the high-temperature pressurized state.

In addition, when the etching part is pressurized as described above, since a pressure in the etching chamber of the etching part and a pressure in the etchant supply part become the same, there is a problem that natural drainage (that is, a method of naturally draining the etchant in the etching chamber to an etchant supply part disposed under the etching chamber using gravity even without using power (for example, a pump which forcibly discharges the etchant from the etching chamber to the etchant supply part) of the etchant in the etching chamber is not easy.

When the drainage of the etchant is not smoothly performed and the etching chamber is immersed in the etchant, there are problems that a process cannot be performed using the etching chamber, the etchant permeates a part connected to the etching chamber causing corrosion or deformation, and thus the etching part is broken.

Accordingly, technology of preventing damage to a bellows in an etchant pump which transfers an etchant from an etchant supply part in an etching part to an etching chamber and smoothly naturally draining the etchant from the etching chamber to the etchant supply part even in a pressurized state of the etching part is required.

The related art of the present invention is disclosed in Korean Patent Registration No. 10-0691479 (Registered on Feb. 28, 2007, ETCHING CHAMBER FOR LARGE AREA SUBSTRATE).

### SUMMARY OF THE INVENTION

The present invention is directed to providing an etching apparatus capable of preventing damage to a bellows in an etchant pump configured to transfer an etchant from an etchant supply part to an etching chamber of the etching apparatus, and a method of controlling the same.

According to an aspect of the present invention, there is provided an etching apparatus including an etching chamber in which a target object is etched by an etchant, an etchant supply part which collects the etchant in the etching chamber and supplies the etchant to the etching chamber using an etchant pump, a first pressure adjusting unit which injects a gas into the etchant pump to apply an operation pressure, a second pressure adjusting unit which pressurizes the etching chamber and the etchant supply part at the same predetermined pressure, a back pressure adjusting unit which adjusts a pressure of the gas discharged when the etchant pump operates, and a valve which controls an order and a direction in which the gas is injected into or discharged from the etchant pump.

The etching apparatus may further include a control unit that selectively controls one or more among the first pressure adjusting unit, the second pressure adjusting unit, the valve, etchant pump, and the back pressure adjusting unit to perform an etching process.

A new pipe branched off from a pipe connected from the second pressure adjusting unit to an etching part including the etching chamber and the etchant supply part may be connected to the back pressure adjusting unit.

The same pressure as the pressure applied to the etching part through the second pressure adjusting unit may be applied to the back pressure adjusting unit through the new pipe.

The control unit may control the first pressure adjusting unit to apply a pressure greater than the pressure applied to the back pressure adjusting unit to the etchant pump.

The etching apparatus may further include a third pressure adjusting unit which independently applies a pressure to the back pressure adjusting unit, wherein the control unit may control the third pressure adjusting unit to apply the same pressure as the pressure applied to the etching part through the second pressure adjusting unit to the back pressure adjusting unit.

The control unit may control the first pressure adjusting unit to apply a pressure greater than the pressure applied from the second pressure adjusting unit or the third pressure adjusting unit.

Discharging pipes of the gas discharged through different paths from the etchant pump through the valve may be merged into one pipe, and one back pressure adjusting unit may be formed in the one pipe formed by merging the discharging pipes of the gas.

The etchant supply part may collect the etchant in the etching chamber in a natural drainage manner through gravity.

According to another aspect of the present invention, there is provided a method of controlling an etching apparatus which includes an etching chamber, an etchant supply part which supplies an etchant to the etching chamber using an etchant pump, a first pressure adjusting unit which injects a gas into the etchant pump to apply an operation pressure, a second pressure adjusting unit which pressurizes the etching chamber and the etchant supply part at predetermined pressures, a back pressure adjusting unit which adjusts a pressure of the gas discharged when the etchant pump operates, a valve which controls an order and a direction in which the gas is injected into or discharged from the etchant pump, and a control unit, the method comprising: selectively controlling, by the control unit, one or more among the first pressure adjusting unit, the second pressure adjusting unit, the valve, the etchant pump, and the back pressure adjusting unit to perform an etching process, and controlling, by the control unit, the first pressure adjusting unit to apply a pressure greater than a pressure applied to the back pressure adjusting unit to the etchant pump.

A new pipe branched off from a pipe connected from the second pressure adjusting unit to an etching part including the etching chamber and the etchant supply part may be connected to the back pressure adjusting unit, and the method may further include applying, by the control unit, the same pressure as a pressure applied to the etching part from the second pressure adjusting unit to the back pressure adjusting unit.

The etching apparatus may further include a third pressure adjusting unit which independently applies a pressure to the back pressure adjusting unit, and the method may further include controlling the third pressure adjusting unit to apply the same pressure as a pressure applied to an etching part through the second pressure adjusting unit to the back pressure adjusting unit.

The method may further include controlling, by the control unit, the first pressure adjusting unit to apply a pressure greater than the pressure applied from the second pressure adjusting unit or the third pressure adjusting unit.

### BRIEF DESCRIPTION OF THE DRAWINGS

The above and other objects, features and advantages of the present invention will become more apparent to those of ordinary skill in the art by describing exemplary embodiments thereof in detail with reference to the accompanying drawings, in which:

FIG. 1 is an exemplary view illustrating a schematic configuration of an etching apparatus according to a first embodiment of the present invention;

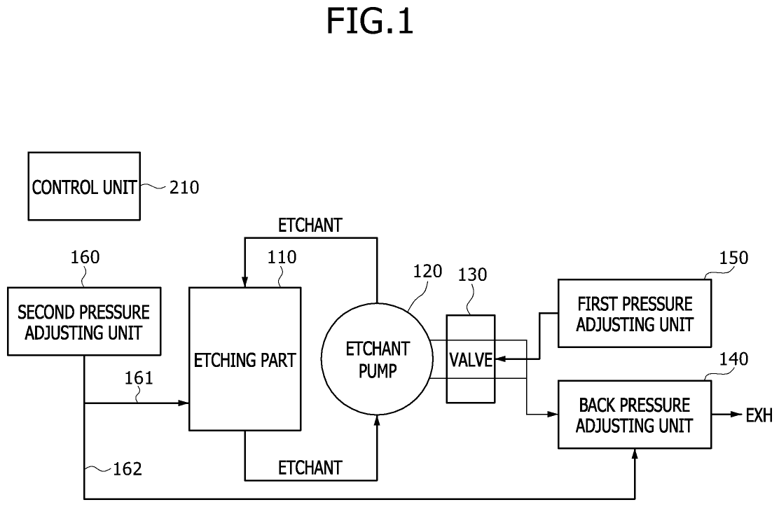

FIG. 2 is an exemplary view illustrating a schematic configuration of an etching apparatus according to a second embodiment of the present invention;

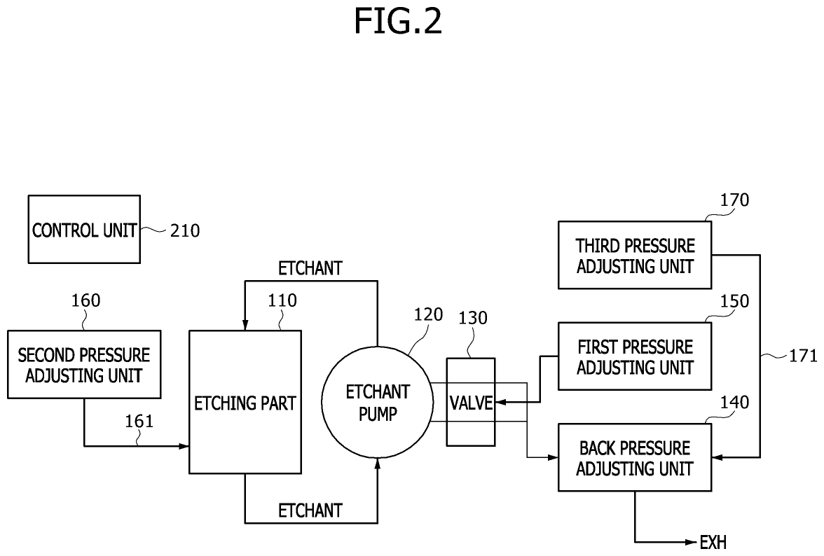

FIG. 3 is a flowchart for describing a method of controlling operations of the etching apparatus illustrated in FIG. 2;

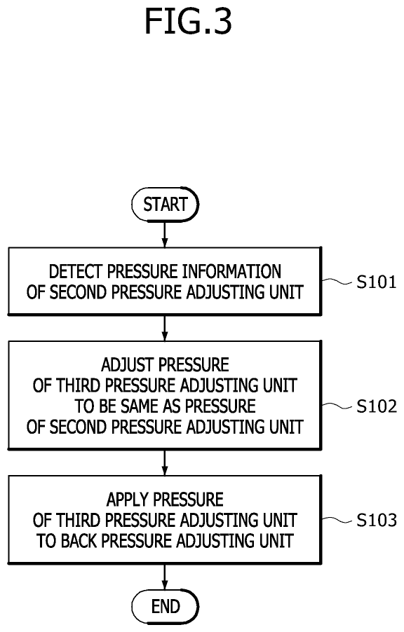

FIG. 4 is an exemplary view for describing operations of an etchant pump in FIG. 1;

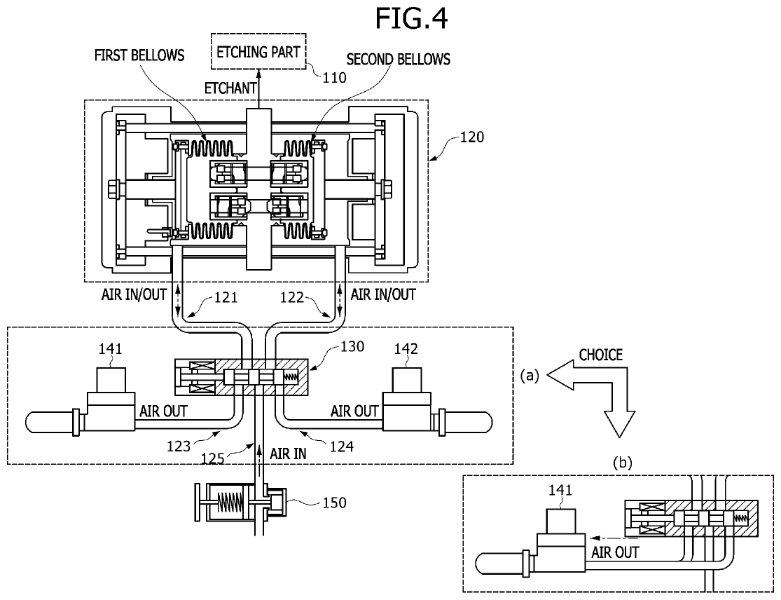

FIG. 5 is an exemplary view illustrating a detailed configuration of an etching part in FIG. 1; and

FIG. 6 is a flowchart for describing a method of controlling operations of the etching apparatus illustrated in FIG. 5.

### DETAILED DESCRIPTION OF EXEMPLARY EMBODIMENTS

second pressure adjusting unit 160 (S102).

In addition, the control unit 210 applies the pressure of the third pressure adjusting unit 170 to the back pressure adjusting unit 140 (S103).

Accordingly, the control unit 210 controls the pressure applied to the back pressure adjusting unit 140 to be the same as a pressure applied to the etching part 110 to prevent damage to a bellows in an etchant pump 120. That is, there is an effect of preventing damage to the bellows by maintaining an external pressure of the etchant pump 120 (for example, a pressure applied to an outer side of the bellows) to be the same as an internal pressure (for example, a pressure by which the bellows is pushed by a pressurized etchant) to prevent deformation or friction of an inner wall of the bellows.

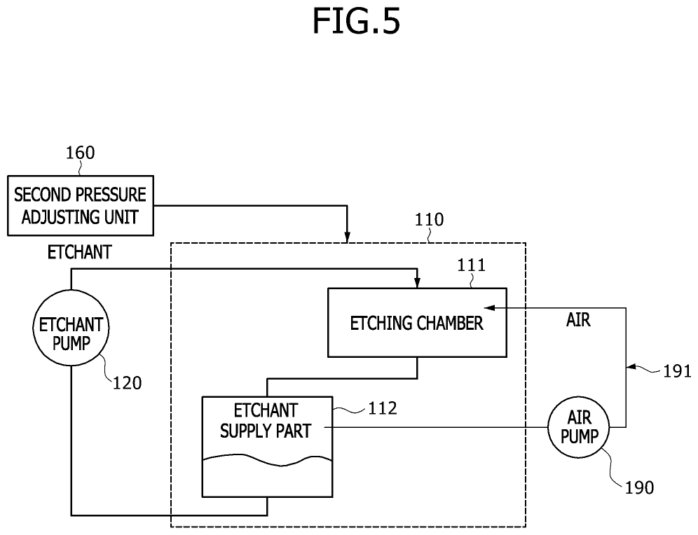

Meanwhile, referring to FIG. 5, the etching part 110 formed as the pressurization system is configured that the etchant supply part 112 is disposed under the etching chamber 111 so that an etchant used in an etching process in the etching chamber 111 is naturally drained to the etchant supply part 112 through an etchant drain pipe by gravity.

However, since a thickness of the etchant drain pipe is small (narrow) and a pressure of the etching chamber 111 and a pressure of the etchant supply part 112 are the same, natural drainage of the etchant is not easy.

Accordingly, in the present embodiment, a gas circulation pipe 191 connecting an upper portion of the etchant supply part 112 (for example, a predetermined point of the upper portion which is positioned higher than a position of the etchant and at which a gas is positioned) and an upper portion of the etching chamber 111 (for example, a predetermined point of the upper portion which is positioned higher than a position of the etchant and at which a gas is positioned) is formed, and an air pump 190 is formed in the middle of the gas circulation pipe 191.

The gas may include air, and thus the air pump 190 forcibly moves air, a gas, or a gas including air through the gas circulation pipe 191.

The air pump 190 forms a separate gas circulation path different from an etchant circulation path by forcibly moving a gas present in the etchant supply part 112 to the etching chamber 111 (that is, generating a pressure difference between two ends of the etchant supply part 112 and the etching chamber 111). By forcibly moving the gas using the air pump 190 as described above, the etchant and the gas of the etching chamber 111 are drained (discharged) to the etchant supply part 112 through the etchant drain pipe in order to maintain a pressure balance (that is, in order to remove a pressure difference).

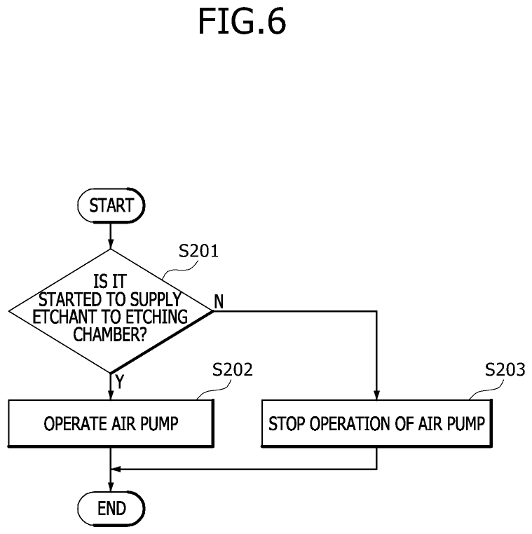

FIG. 6 is a flowchart for describing a method of controlling operations of the etching apparatus illustrated in FIG. 5, and shows that when the etching apparatus starts operation to supply an etchant to the etching chamber 111 through the etchant pump 120 (Y in S201), the control unit 210 operates the air pump 190 at a predetermined speed (S202).

Accordingly, as a gas present in the etchant supply part 112 is forcibly moved to the etching chamber 111, the etchant and the gas of the etching chamber 111 are drained (discharged) to the etchant supply part 112 through the etchant drain pipe in order to maintain a pressure balance. That is, even in a pressurized state of the etching part 110, the etchant is smoothly drained from the etching chamber 111 to the etchant supply part 112.

Meanwhile, when the operation of the etching apparatus stops or the operation of the etchant pump 120 stops to stop the supply of the etchant to the etching chamber 111 (N in S201), the control unit 210 immediately stops the operation of the air pump 190 (S203).

Accordingly, since the gas present in the etchant supply part 112 does not flow to the etching chamber 111, the etchant and the gas of the etching chamber 111 are not naturally drained (discharged) to the etchant supply part 112 through the etchant drain pipe.

As described above, the present embodiment has an effect of naturally draining the etchant to the etchant supply part 112 disposed under the etching chamber 111 due to gravity even without using a drain pump (not shown) which forcibly discharges the etchant from the etching chamber 111 to the etchant supply part 112 (that is, when the drain pump is used, there may be a problem in forming an etching atmosphere because synchronization between the drain pump and the etchant pump is not easy). According to embodiments of the present invention, damage to a bellows in an etchant pump configured to transfer an etchant from an etchant supply part to an etching chamber of an etching apparatus can be prevented.

While the present invention has been described with reference to embodiments illustrated in the accompanying drawings, this is merely exemplary. It will be understood by those skilled in the art that various modifications and other equivalent example embodiments may be made from the embodiments of the present invention. Therefore, the scope of the present invention is defined by the appended claims. In addition, the present invention described in this specification can be implemented through, for example, a method, a process, an apparatus, a software program, a data stream, or a signal. Even when the present invention is described as being implemented in only a single way (for example, as a method), the described features may be implemented in another way (for example, as an apparatus or program). An apparatus may be implemented using hardware, software, firmware, or the like. A method may be implemented in an apparatus such as a processor which generally indicates a processing device such as a computer, a microprocessor, an integrated circuit, and a logic device capable of being programmed. Examples of a processor also include a communication device such as a computer, a cell phone, a portable/personal digital assistant (PDA), and another device which facilitates information communication between end-users.

What is claimed is:

1. An etching apparatus comprising:
an etching chamber in which a target object is etched by an etchant;
an etchant supply part which collects the etchant in the etching chamber and supplies the etchant to the etching chamber using an etchant pump;
a first pressure adjusting unit which injects a gas into the etchant pump to apply an operation pressure;
a second pressure adjusting unit which pressurizes the etching chamber and the etchant supply part at the same predetermined pressure;
a back pressure adjusting unit which adjusts a pressure of the gas discharged when the etchant pump operates; and
a valve which controls an order and a direction in which the gas is injected into or discharged from the etchant pump.

2. The etching apparatus of claim 1, further comprising a control unit that selectively controls one or more among the first pressure adjusting unit, the second pressure adjusting unit, the valve, etchant pump, and the back pressure adjusting unit to perform an etching process.

3. The etching apparatus of claim 1, wherein a new pipe branched off from a pipe connected from the second pressure adjusting unit to an etching part including the etching chamber and the etchant supply part is connected to the back pressure adjusting unit.

4. The etching apparatus of claim 3, wherein the same pressure as the pressure applied to the etching part through the second pressure adjusting unit is applied to the back pressure adjusting unit through the new pipe.

5. The etching apparatus of claim 2, wherein the control unit controls the first pressure adjusting unit to apply a pressure greater than the pressure applied to the back pressure adjusting unit to the etchant pump.

6. The etching apparatus of claim 2, further comprising a third pressure adjusting unit which independently applies a pressure to the back pressure adjusting unit,
wherein the control unit controls the third pressure adjusting unit to apply the same pressure as the pressure applied to the etching part through the second pressure adjusting unit to the back pressure adjusting unit.

7. The etching apparatus of claim 6, wherein the control unit controls the first pressure adjusting unit to apply a pressure greater than the pressure applied from the second pressure adjusting unit or the third pressure adjusting unit.

8. The etching apparatus of claim 1, wherein:
discharging pipes of the gas discharged through different paths from the etchant pump through the valve are merged into one pipe; and
one back pressure adjusting unit is formed in the one pipe formed by merging the discharging pipes of the gas.

9. The etching apparatus of claim 1, wherein the etchant supply part collects the etchant in the etching chamber in a natural drainage manner through gravity.

10. A method of controlling an etching apparatus which includes an etching chamber, an etchant supply part which supplies an etchant to the etching chamber using an etchant pump, a first pressure adjusting unit which injects a gas into the etchant pump to apply an operation pressure, a second pressure adjusting unit which pressurizes the etching chamber and the etchant supply part at predetermined pressures, a back pressure adjusting unit which adjusts a pressure of the gas discharged when the etchant pump operates, a valve which controls an order and a direction in which the gas is injected into or discharged from the etchant pump, and a control unit,
wherein the method comprises:
selectively controlling, by the control unit, one or more among the first pressure adjusting unit, the second pressure adjusting unit, the valve, the etchant pump, and the back pressure adjusting unit to perform an etching process; and
controlling, by the control unit, the first pressure adjusting unit to apply a pressure greater than a pressure applied to the back pressure adjusting unit to the etchant pump.

11. The method of claim 10, further comprises applying, by the control unit, the same pressure as a pressure applied to an etching part from the second pressure adjusting unit to the back pressure adjusting unit,
wherein a new pipe branched off from a pipe connected from the second pressure adjusting unit to an etching part including the etching chamber and the etchant supply part is connected to the back pressure adjusting unit.

12. The method of claim 10, further comprising controlling a third pressure adjusting unit to apply the same pressure as a pressure applied to an etching part through the second pressure adjusting unit to the back pressure adjusting unit,
wherein the etching apparatus further includes the third pressure adjusting unit which independently applies a pressure to the back pressure adjusting unit.

13. The method of claim 12, further comprising controlling, by the control unit, the first pressure adjusting unit to apply a pressure greater than the pressure applied from the second pressure adjusting unit or the third pressure adjusting unit.
